(19) United States
(12) Patent Application Publication
(10) Pub. No.: US 2026/0087203 A1
(43) Pub. Date: Mar. 26, 2026

(54) AUTOMATED GAP DETECTION AND REMOVAL IN GEOMETRICAL OR THREE-DIMENSIONAL MODELS FOR ENHANCED SIMULATION READINESS

(71) Applicant: Simerics, Inc., Bellevue, WA (US)

(72) Inventors: Yu Jiang, Bellevue, WA (US); Michal Furmanczyk, Bellevue, WA (US)

(21) Appl. No.: 19/234,731

(22) Filed: Jun. 11, 2025

Related U.S. Application Data
(60) Provisional application No. 63/698,755, filed on Sep. 25, 2024.

(51) Int. Cl. G06F 30/23; G06F 30/28; G06T 17/20

(52) U.S. Cl. CPC G06F 30/23; G06F 30/28; G06T 17/205

(57) ABSTRACT

The present invention presents a computer-implemented method for automatically identifying and sealing gaps in geometrical or three-dimensional models for simulation. The method involves creating a multi-volume mesh of the model, defining boundaries to distinguish inside and outside regions, and solving the Laplace equation to identify gaps. By adjusting the iso-surface of the equation's primary variable, the gaps are sealed at desired locations. The model is then divided into distinct inner and outer volumes. The process reduces manual intervention, ensures accurate simulation preparation, and allows user interaction for boundary definition and visualization. The invention streamlines model preparation for simulations, enhancing the efficiency and accuracy of design validation across various industries and allowing much more efficient analysis.

### CROSS-REFERENCE

This application claims the benefit of U.S. Provisional Patent Application No. 63/698,755, filed on 25 Sep. 2024, entitled ‘AUTOMATED GAP DETECTION AND REMOVAL IN GEOMETRICAL OR THREE-DIMENSIONAL MODELS FOR ENHANCED SIMULATION READINESS,’ the entire contents of which are incorporated herein by reference.

### FIELD OF THE INVENTION

The present invention relates to design and simulation technologies, specifically to methods and systems for preparing geometrical or three-dimensional models for simulation by automatically detecting and removing gaps between parts in three-dimensional geometry models. This invention addresses challenges in model validation, improving the efficiency and accuracy of simulations used in product design and development and allows much more efficient analysis.

### BACKGROUND

The use of CAD software for designing prototypes has become a standard practice across various industries. CAD software allows engineers and designers to create detailed models of new products, enabling them to visualize and refine their designs before moving forward with physical production. This practice is often followed by validation of the prototype through simulations, which utilize CAD designs as input. Simulation techniques are increasingly popular due to their ability to provide faster turnaround times and substantial cost savings compared to traditional build and test methodologies. However, one of the persistent challenges in this process is the issue of gaps in the CAD models. These gaps typically arise from normal tolerances, imperfections in the CAD surface representation, or errors during assembly within the software. These discrepancies between parts result in a 3D geometry model that is unsuitable for simulation software, as the gaps can distort results or prevent the simulation from running altogether. The presence of gaps compromises the accuracy of the simulation, leading to potential delays in the design validation process. Currently, addressing these gaps requires manual intervention, which involves identifying and closing each gap individually within the CAD model. This is a tedious and time-consuming task, especially for large and complex models with numerous solid parts. In many instances, the process of manually fixing these gaps can extend over several days, weeks, or even months, thus significantly impeding the overall design and development timeline. The inefficiency of this manual process highlights the need for an automated solution that can quickly and accurately prepare CAD models for simulation by eliminating the problematic gaps, thereby accelerating the simulation phase and reducing costs.

### SUMMARY

The present invention provides an automated method for identifying and scaling gaps in geometrical or three-dimensional models (for example, CAD models) to prepare them for simulation. The process begins by creating a multi-volume mesh that encompasses all relevant bodies and surfaces. To differentiate between internal and external volumes, the user defines boundaries or points, serving as markers to identify gaps. The invention then employs the Laplace equation due to its properties that allow for accurate distinction between inside and outside volumes. The primary variable of this equation possesses a unique characteristic: its gradient is inversely proportional to the area it traverses, ensuring that the solution reaches constant values in the absence of gaps or holes. By solving the Laplace equation over the mesh, the invention identifies regions where the primary variable changes rapidly, indicative of gaps or holes. An iso-surface of the primary variable solution is then computed to visually inspect and identify the gaps. By adjusting the iso-surface values, the user can achieve the scaling of gaps at desired locations. This technique allows for the selective closing of gaps, even one at a time if necessary, ensuring optimal closure and separation of volumes. The final step involves creating two distinct volumes using this iso-surface: the inside and outside of the gaps. This automated approach streamlines the process of gap removal, significantly reducing the time required for the model preparation and ensuring that the resulting geometry is suitable for accurate simulations.

The present invention further provides a computer-implemented method for automatically identifying and sealing gaps in geometrical or three-dimensional (3D) models (such as computer-aided design (CAD) models) to prepare them for simulation purposes. The method addresses common issues in geometry that can hinder accurate simulation, such as gaps caused by imperfections or tolerances between model components. By automating this gap-scaling process, the invention significantly reduces the manual effort and time typically required to make a geometrical or three-dimensional model such as a CAD model suitable for simulation, thus improving design validation workflows. The method begins by constructing a multi-volume mesh that includes all bodies and surfaces relevant to the simulation. Boundaries or points are then defined within the 3D model to distinguish inside and outside regions, with gaps situated at the interfaces of these regions. An equation with specific properties is employed over the multi-volume mesh: it allows the primary variable to have a maximum value at the boundaries or source point, ensures that the gradient of the primary variable is inversely proportional to the area through which it can pass, and results in two constant values for the inside and outside regions when no gaps are present. The Laplace equation is chosen for this purpose due to its simplicity and its fulfillment of these conditions. The method proceeds by setting appropriate active or inactive volumes and applying zero-gradient conditions at all other boundaries to solve the Laplace equation over the multi-volume mesh. An iso-surface of the primary variable solution is then identified, and its value is iteratively adjusted until gaps within the model are sealed at desired locations. This step allows for flexible sealing, even addressing one gap at a time if needed. Once the gaps are sealed, the model is divided into distinct inside and outside volumes using the iso-surface. The user can visualize a cross-sectional view of the iso-surface to verify the gap-scaling process, ensuring that the separation is accurate. Further refinement is possible through user interaction, allowing boundaries or points to be specified via a graphical user interface. Additionally, the separated volumes can be selectively managed, such as deleting the outer volume to retain a clean inner model for specific simulations. This versatility enables the method to be applied to various simulation types, including fluid dynamics, thermal analysis, structural testing, finite element analysis, and electromagnetic analysis, but should not be construed as limiting to the scope of the present invention. Overall, the invention provides an efficient, accurate, and automated approach to preparing the models for simulation, enhancing the design validation process and reducing potential errors caused by improper geometry handling.

The present invention further provides a system for automatically identifying and scaling gaps in a three-dimensional (3D) computer-aided design (CAD) model for simulation. The system comprises a processor configured to execute instructions stored in a memory to perform gap identification and scaling. The system further comprises a multi-volume meshing module configured to generate a mesh encompassing all CAD bodies and surfaces of the 3D model relevant to a simulation. The system further comprises a boundary definition module configured to define boundaries or points within the 3D model to distinguish inside and outside regions, wherein gaps exist between these regions. The system further comprises a solver module configured to execute a Laplace equation over the multi-volume mesh, wherein the equation satisfies the conditions that its primary variable has a maximum value either at the boundaries or in the source term, has a gradient inversely proportional to the area through which it can pass, and results in two constant values for the inside and outside regions in the absence of gaps. The system further comprises an iso-surface computation module configured to determine an iso-surface of the primary variable solution and iteratively adjust its value until gaps in the 3D model are sealed at desired locations. The system further comprises a volume separation module configured to segment the 3D model into distinct inside and outside volumes using the computed iso-surface, ensuring the gaps are sealed. The system further comprises a graphical user interface (GUI) module configured to allow a user to interactively define boundaries, visualize the iso-surface, inspect the sealing process, and selectively delete inner or outer volumes as needed for simulation preparation.

The primary advantage of this invention is its ability to automate the detection and sealing of gaps in geometrical or three-dimensional models, drastically reducing the time and effort typically required for manual gap closure. By utilizing the properties of the Laplace equation, the invention ensures accurate identification of gaps and their optimal closure, enhancing the reliability of simulation results. This not only accelerates the design validation process but also minimizes errors that could arise from incomplete or faulty geometry. Applications of this technology span various industries that rely on simulation, such as automotive, aerospace, construction, and manufacturing. For example, engineers can use this method to prepare complex 3D models for simulations of fluid dynamics, thermal analysis, structural stress testing, and airflow analysis, allowing for faster product development cycles and improved design quality.

### BRIEF DESCRIPTION OF THE ACCOMPANYING DRAWINGS

The novel features which are believed to be characteristic of the present invention, as to its structure, organization, use, and method of operation, together with further objectives and advantages thereof, will be better understood from the following drawings in which a presently preferred embodiment of the invention will now be illustrated by way of example. It is expressly understood, however, that the drawings are for the purpose of illustration and description only and are not intended as a definition of the limits of the invention. Embodiments of this invention will now be described by way of example in association with the accompanying drawings in which:

FIG. 1 is a diagram that illustrates a hollow box with a leakage hole due to modelling error, in accordance with an embodiment of the present invention.

FIG. 2 is a diagram that illustrates inside and outside of the box, in accordance with an embodiment of the present invention.

FIG. 3 is a diagram that illustrates mesh leaked through a leakage gap, in accordance with an embodiment of the present invention.

FIG. 4 is a diagram that illustrates a preview of the inner volume after cutting off leakage and a cross-section of the leakage path, in accordance with an embodiment of the present invention.

FIG. 5 is a diagram that illustrates the separated volumes, in accordance with an embodiment of the present invention.

FIG. 6 is a diagram that illustrates before and after deleting the outer volume, in accordance with an embodiment of the present invention.

FIGS. 7-11 are diagrams that illustrate an exemplary solution, in accordance with an embodiment of the present invention.

FIG. 12 is a block diagram that illustrates a system for performing the disclosed method operation, in accordance with an embodiment of the present invention.

FIG. 13 is a diagram that illustrates a flowchart of a method for automatically identifying and sealing gaps in a geometrical or three-dimensional model for simulation purposes, in accordance with an embodiment of the present invention.

Further areas of applicability of the present invention will become apparent from the detailed description provided hereinafter. It should be understood that the detailed description of exemplary embodiments is intended for illustration purposes only and is, therefore, not intended to necessarily limit the scope of the invention.

### DETAILED DESCRIPTION

As used in the specification and claims, the singular forms “a”, “an”, and “the” may also include plural references. For example, the term “an article” may include a plurality of articles. Those with ordinary skill in the art will appreciate that the elements in the Figures are illustrated for simplicity and clarity and are not necessarily drawn to scale. For example, the dimensions of some of the elements in the Figures may be exaggerated, relative to other elements, to improve the understanding of the present invention. There may be additional components described in the foregoing application that are not depicted on one of the described drawings. In the event such a component is described, but not depicted in a drawing, the absence of such a drawing should not be considered as an omission of such design from the specification.

References to “one embodiment”, “an embodiment”, “another embodiment”, “yet another embodiment”, “one example”, “an example”, “another example”, “yet another example”, and so on, indicate that the embodiment(s) or example(s) so described may include a particular feature, structure, characteristic, property, element, or limitation, but that not every embodiment or example necessarily includes that particular feature, structure, characteristic, property, element or limitation. Furthermore, repeated use of the phrase “in an embodiment” does not necessarily refer to the same embodiment.

The words “comprising,” “having,” “containing,” and “including,” and other forms thereof, are intended to be equivalent in meaning and be open ended in that an item or items following any one of these words is not meant to be an exhaustive listing of such item or items or meant to be limited to only the listed item or items. Unless stated otherwise, terms such as “first” and “second” are used to arbitrarily distinguish between the elements. Thus, these terms are not necessarily intended to indicate temporal or other prioritization of such elements. While various exemplary embodiments of the disclosed invention have been described below it should be understood that they have been presented for purposes of example only, not limitations. It is not exhaustive and does not limit the invention to the precise form disclosed. Modifications and variations are possible considering the above teachings or may be acquired from practicing of the invention, without departing from the breadth or scope.

Three-dimensional (3D) Computer-Aided Design (CAD) models are widely used in engineering simulations, including Computational Fluid Dynamics (CFD) and Finite Element Analysis (FEA). However, one of the most persistent issues in preparing these models for simulation is the presence of gaps, slivers, and tolerances that result from geometric imperfections, assembly misalignments, or CAD modeling errors. These gaps prevent the creation of a continuous simulation domain, leading to errors in meshing, incorrect boundary conditions, and inaccurate or non-converging simulation results. Traditional approaches require manual correction, which is time-consuming, labor-intensive, and prone to human error, especially in large and complex models such as automotive and aerospace components. Additionally, improper scaling of gaps can lead to fluid leakage, heat dissipation errors, and incorrect force calculations in simulations, significantly reducing the reliability of engineering analysis. Therefore, there is a critical need for an automated system that can identify, classify, and seal gaps efficiently, ensuring a simulation-ready model without requiring extensive manual intervention. To address these issues, the invention introduces a computer-implemented method that automates the detection and scaling of gaps within 3D CAD models using multi-volume meshing, numerical solvers, iso-surface computations, and volume separation techniques. The system first creates a multi-volume mesh that encompasses all bodies and surfaces of the 3D model, ensuring that all geometric details are captured in a computationally efficient format. This multi-volume mesh provides the necessary computational framework for identifying and analyzing the gaps that need to be sealed. The next step involves defining boundaries or points within the 3D model to separate the inside and outside regions, ensuring that the method correctly identifies where the gaps are located. These boundaries are crucial in distinguishing the fluid region, structural domains, and external surfaces, ensuring that the simulation maintains physical realism. The system applies a mathematical solver, specifically the Laplace equation, to the multi-volume mesh.

The Laplace equation is chosen because it meets three essential criteria:
The primary variable of the equation reaches a maximum value at the boundaries or source point, ensuring accurate boundary distinction.
The gradient of the primary variable is inversely proportional to the area through which it can pass, enabling precise detection of discontinuities such as gaps.
In the absence of gaps, the equation produces two constant values corresponding to the inside and outside regions, ensuring a stable solution.

The Laplace equation is solved across the mesh by setting appropriate active and inactive volumes, ensuring that the focus remains on the regions requiring gap sealing. The equation is solved using finite element (FE) or finite difference (FD) numerical methods, ensuring a highly accurate separation of volumes. The solver computes a scalar field distribution, which serves as the foundation for further processing.

Once the numerical solver has processed the Laplace equation, the system proceeds with iso-surface computation to detect and seal the gaps. The iso-surface represents a constant value of the primary variable, allowing it to be used as a geometric separator between inside and outside volumes. The system iteratively adjusts the iso-surface value until all gaps in the 3D model are sealed at the desired locations. This ensures that the final model has fully enclosed volumes, eliminating any leakage paths that could compromise simulation accuracy. Additionally, the system includes an adaptive meshing technique that refines the mesh resolution near detected gaps to enhance the accuracy of sealing. This ensures that even microscopic gaps and slivers are identified and closed correctly, preventing simulation instability. The iso-surface computation dynamically adjusts its threshold values based on the rate of change of the primary variable across the mesh, ensuring optimized sealing of gaps based on geometry-specific characteristics.

After sealing the gaps, the system proceeds with volume separation, where the 3D model is divided into distinct inside and outside volumes. This is crucial in simulations requiring separate airflow regions, thermal boundaries, or mechanical enclosures. The volume separation step is performed iteratively, refining the boundary until a predefined convergence criterion for boundary integrity is met. Once the model is separated into distinct inner and outer volumes using the computed iso-surface, the system allows for flexible post-processing depending on the simulation requirements. In some cases, the user may choose to retain both volumes, particularly when simulations or validations require analysis of interactions across the boundary or when future use of both domains is anticipated. Alternatively, the system also provides the option to selectively delete either the inner or outer volume, allowing the users to isolate and retain only the required computational domain such as keeping the internal fluid domain while removing the external solid shell, or vice versa. This flexibility ensures that the method accommodates a wide range of use cases across engineering domains, supporting both targeted domain isolation and comprehensive model retention, depending on the specific simulation or design objectives.

To enhance usability, the invention includes a graphical user interface (GUI) that allows users to: define boundaries interactively using a visual interface, modify the iso-surface threshold values in real-time to inspect the effect of gap sealing, and display a cross-sectional view of the model to visually verify how gaps are sealed. These interactive features provide full control and validation to engineers, ensuring that the final model meets the necessary simulation constraints before proceeding with analysis.

To ensure the integrity of the sealed model, the system includes a volume integrity check that validates whether the inner and outer volumes are fully enclosed without residual gaps. If any anomalies are detected, the system triggers an error-correction module that automatically identifies and reprocesses the affected regions, ensuring a completely stable solution. Once validated, the model is automatically converted into a simulation-ready CAD file format, ensuring compatibility with industry-standard software such as Finite Element Analysis (FEA), Computational Fluid Dynamics (CFD), or Structural Simulation Tools. This step eliminates the need for manual CAD adjustments, significantly reducing preparation time for simulations. The system also includes intelligent gap classification, where gaps are analyzed based on their size, shape, and impact on simulation stability. A priority-based sealing approach is applied to first close the most significant gaps before addressing minor imperfections, optimizing both efficiency and computational accuracy. Additionally, the system logs all sealed gaps, creating a detailed audit trail that allows users to review modifications, track changes, and ensure compliance with engineering standards.

The invention will now be described with reference to the accompanying drawings which should be regarded as merely illustrative without restricting the scope and ambit of the present invention. Before describing the present invention in detail, it should be observed that the present invention discloses a systematic approach to solving the problem of gaps in geometrical or three-dimensional models by using a multi-volume mesh, boundary identification, and the application of Laplace's equation to detect and seal gaps. The disclosed process offers an innovative automated solution for preparing the models for simulations, significantly enhancing efficiency and accuracy and allows much more efficient analysis.

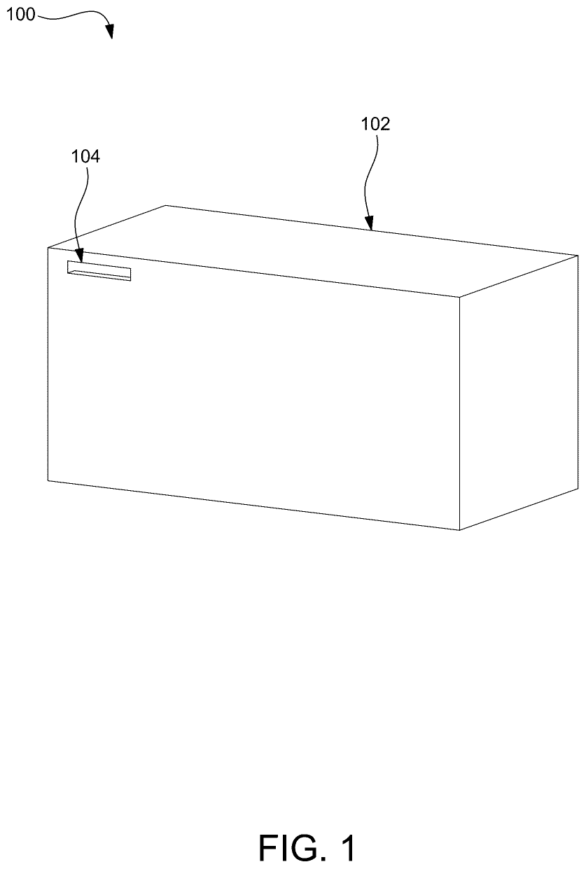

FIG. 1 is a diagram 100 that illustrates a hollow box 102 with a leakage hole 104 due to modelling error, in accordance with an embodiment of the present invention. As shown, FIG. 1 illustrates a simple demonstration case of the hollow box 102 with the leakage hole 104. This hole represents a common issue encountered in models, where imperfections or errors in the geometry create unintended gaps or openings. In this example, the leakage hole is an unintended defect in the CAD representation, which does not exist in the real physical design of the product. These types of errors can occur due to inaccuracies in the CAD surface modeling or assembly process, leading to a geometry that is unsuitable for simulation purposes. The figure highlights the problem that the invention aims to address. The hollow box 102 serves as an example of a 3D model that may fail in simulation software due to the existence of gaps or holes. The hole here is indicative of how minor imperfections in CAD geometry can compromise the integrity of the model, resulting in inaccurate simulation results. The invention described uses a method to automatically identify and seal such gaps, ensuring that the CAD model is properly prepared for simulation, ultimately saving time and improving the accuracy of the product development process and allowing much more efficient analysis.

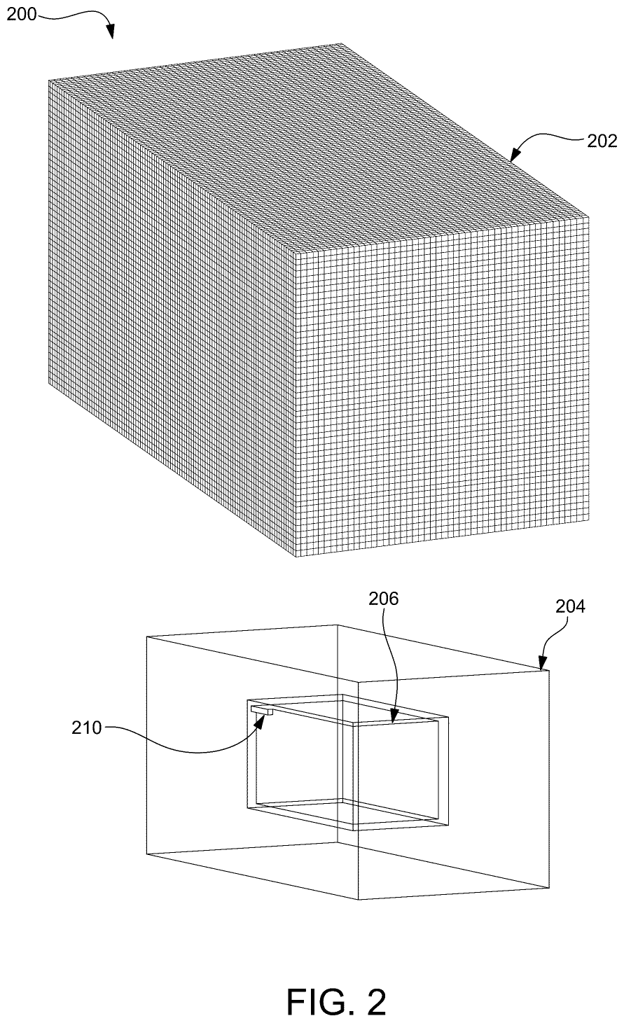

FIG. 2 is a diagram 200 that illustrates inside and outside of the box 102, in accordance with an embodiment of the present invention. As shown, FIG. 2 demonstrates the challenges of creating a fluid mesh for the hollow box 102 (FIG. 1) with the leakage hole 104 (FIG. 1) due to imperfections in the CAD geometry. On the top, the image shows the outside volume mesh view 202, illustrating how the meshing software creates a grid-like structure around the entire model, encompassing both the inside and outside of the hollow box 102. Due to the presence of the leakage hole 104, the mesh fails to correctly distinguish between the interior and exterior of the box. This results in a connection between the internal and external volumes through the hole, effectively causing the mesh to “leak” from the inside to the outside. This mesh leakage compromises the integrity of the simulation, leading to inaccurate or unusable results. The bottom side of FIG. 2 provides the outline showing the structure of the meshed volume 204. Here, the inside lines 206 outline the original hollow box 102 within the external mesh volume. The diagram visually indicates that the meshed volume does not isolate the box's internal space, further emphasizing how the leakage hole 104 disrupts the separation of internal and external regions. This leakage causes problems when performing simulations, as fluid flow, thermal transfer, or other physical properties cannot be accurately analyzed. The figure illustrates the critical need for an automated solution to identify and seal such gaps, allowing for proper mesh generation and reliable simulations. The invention discussed aims to address this issue by automatically detecting the gaps 210 and creating distinct inside and outside volumes, thus preventing mesh leakage.

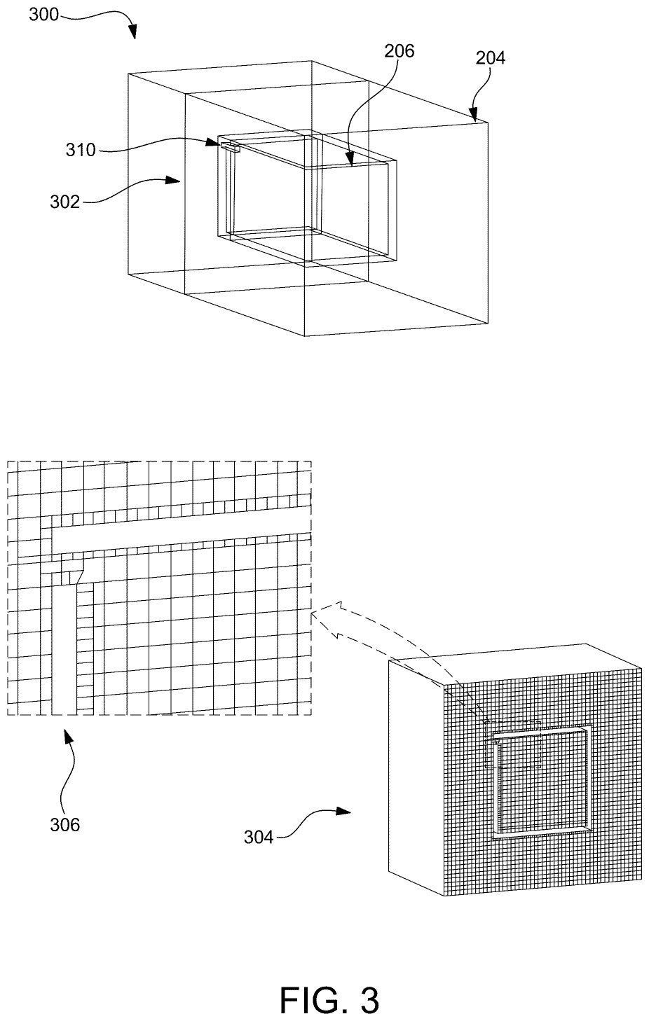

FIG. 3 is a diagram 300 that illustrates mesh leaked through the leakage gap 310, in accordance with an embodiment of the present invention. FIG. 3 illustrates a more detailed view of the leakage issue in the meshed model caused by gaps in the CAD geometry. It shows a cut-plane view through the hollow box 102 (FIG. 1) to highlight how the mesh leaks through the gap 310. The figure consists of three parts: an overall cut-plane visualization 302, a closer view of the meshed interior, 304 and a zoomed-in section to explicitly show the leakage 306.

The top image 302 provides a cut-plane perspective of the hollow box 102, allowing for a clear view of the internal structure. This visualization makes it easier to inspect the internal mesh and identify any discrepancies in the geometry. The bottom images (304 and 306) depict the cut-plane with the mesh applied to the internal and external regions of the box 102. Here, the problematic area is marked as shown, indicating the location of the leakage gap 104. This shows that the mesh has not been contained correctly within the box's interior and exterior boundaries due to the presence of the gap. The zoomed-in section 306 provides a detailed view of the mesh at the gap. It clearly demonstrates how the mesh has “leaked” through the gap 310, which disrupts the distinction between the inside and outside volumes. This mesh leakage occurs because the gap creates a path that allows the mesh elements to cross over the intended boundary, thereby corrupting the geometry for simulation purposes.

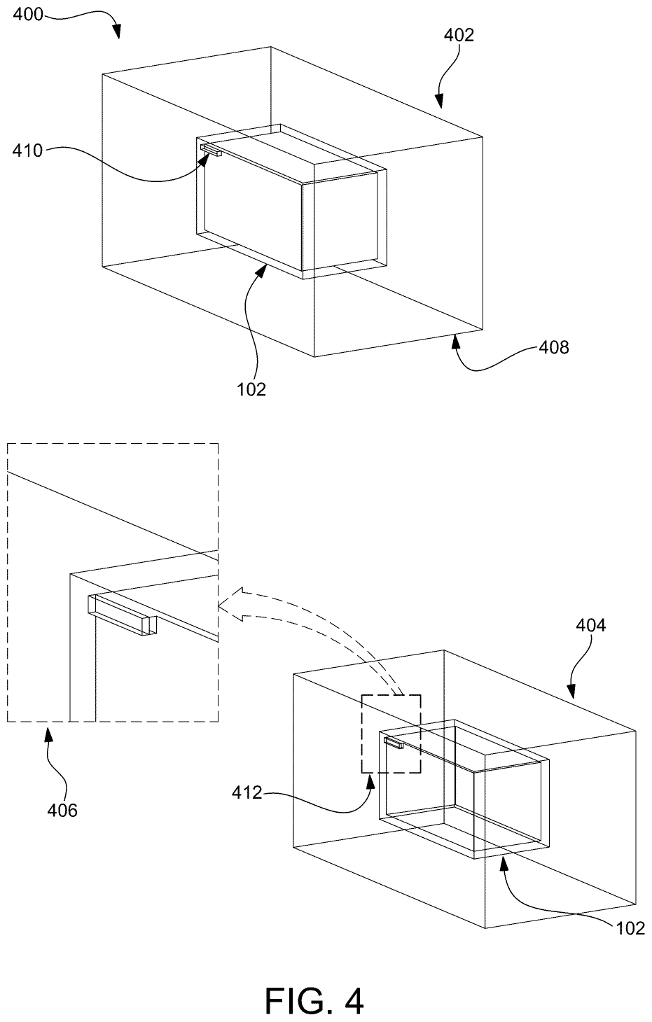

FIG. 4 is a diagram 400 that illustrates a preview of the inner volume after cutting off leakage and a cross-section of the leakage path, in accordance with an embodiment of the present invention. As shown, FIG. 4 demonstrates the application of the “SEAL (super-efficient automatic leakage stopper)” algorithm, which is the automated solution for identifying and sealing leakage paths in CAD models. The figure is divided into three parts: a preview of the inner volume after applying the algorithm 402, a cross-section of the leakage path 404, and a detailed view of the cross-section 406. The top image shows a preview of the inner volume after the leakage has been sealed using the SEALS (super-efficient automatic leakage stopper) algorithm. Here, the hollow box 102 is enclosed within the external boundaries 408. The algorithm effectively identifies the gap 410 (previously causing the mesh leakage) and seals it, allowing the meshing software to correctly distinguish between the inside and outside volumes of the box 102. This enables the proper simulation of fluid flow, thermal behavior, or other relevant physical properties. The visualization helps the user ensure that the leakage path has been appropriately sealed, and the model is ready for accurate simulations. The bottom image presents a cross-section of the box 102, providing a detailed view of the location of the leakage path 412. This cross-sectional inspection allows the user to see where the gap 410 existed and verify that the “SEALS” algorithm has successfully closed it. The cross-section can be adjusted to different locations as needed by the user to inspect other potential gaps or verify the sealing process. The zoomed-in section 406 provides a closer look at the cross-section of the leakage path 412. This detailed view illustrates how the “SEALS” algorithm has sealed the gap, converting the open path into a closed boundary. The shaded region indicates where the algorithm has filled in the gap, ensuring no mesh leakage will occur in the final simulation model. This figure underscores the capabilities of the “SEALS” algorithm in automatically identifying and scaling gaps in CAD geometry. By providing tools for cross-sectional analysis and visualization, users can interactively inspect the results and ensure all leakages are properly addressed. This not only accelerates the model preparation process but also ensures the integrity and accuracy of the resulting simulations, making this solution highly beneficial for various engineering applications and allowing much more efficient analysis.

The algorithm provides a methodical approach to identifying and sealing gaps in geometrical or three-dimensional (e.g., CAD) models using a multi-step process that involves meshing, boundary definition, and solving the Laplace equation. The detailed breakdown includes:

Step 1: Building a Multi-Volume Mesh—The first step involves constructing a multi-volume mesh that includes all the bodies and surfaces that are relevant to the simulation. This mesh represents the complex geometry of the model, including potential gaps or holes between different parts. Creating this mesh is essential as it provides the framework on which the gap detection and scaling process will be applied.

Step 2: Boundary or Point Identification—In this step, the user specifies boundaries or points to differentiate between the inside and outside regions of the model. This identification is crucial because the volumes inside and outside the gaps are connected through those gaps. Defining these boundaries helps to demarcate the areas that the algorithm will target for gap detection and closure, serving as reference points for the following steps.

Step 3: Utilizing the Equation with Specific Properties—The next step is to employ an equation that has certain properties which allow for the detection and sealing of gaps. The chosen equation must: (a) Ensure that the primary variable can have a maximum value either at the boundaries or in the source point. This property helps in defining the extremes of the volume. (b) Have a gradient that is inversely proportional to the area through which it passes, which allows the equation to respond sensitively to changes in the geometry, especially near gaps. (c) Provide a solution where the primary variable has two constant values that represent the inside and outside of the volume, indicating that the volume is completely sealed if there are no gaps.

Step 4: Selection of the Laplace Equation—The algorithm selects the Laplace equation due to its simplicity and its ability to meet the conditions specified in Step 3. The Laplace equation is a second-order partial differential equation that models how the primary variable (e.g., potential or temperature) distributes itself across the mesh. It's an ideal choice for detecting geometric discontinuities because its solution changes smoothly except at boundaries, where gaps or holes are present.

Step 5: Solving the Laplace Equation—Once the mesh and boundaries are established, the Laplace equation is solved over the specified volume. Inactive volumes and all other boundaries are set to a zero gradient, which means that the primary variable will not change across these boundaries. This focus ensures that the equation's solution only responds to the regions of the mesh where gaps or holes are present. Essentially, this step isolates the problematic areas and prevents unnecessary modifications to the rest of the mesh.

Step 6: Identifying the Iso-Surface—The algorithm then finds an iso-surface of the primary variable's solution, which is a surface representing a constant value of that variable. By adjusting the value of this iso-surface, the algorithm inspects the mesh to locate and seal gaps. The rapid changes in the primary variable around the gaps allow for their identification. If needed, the process can be applied incrementally, sealing one gap at a time to ensure optimal closure. This flexible approach enables the user to fine-tune the sealing process for complex geometries. While the iso-surface method may be the preferred one and is currently implemented approach due to its efficiency in visualizing and separating inside and outside volumes, alternative techniques such as detecting regions with high gradient values or using specific cell value thresholds may also be employed depending on implementation needs. These additional methods offer flexibility in adapting the algorithm for different computational frameworks or model characteristics.

Step 7: Separating the Volume—In the final step, the iso-surface is used to create two distinct volumes: the inside and outside regions of the gaps or holes. This separation effectively seals the gaps, allowing for a clean division between internal and external spaces. This outcome ensures that the mesh is now suitable for simulation, free from leakage paths that would otherwise compromise the accuracy of the simulation results.

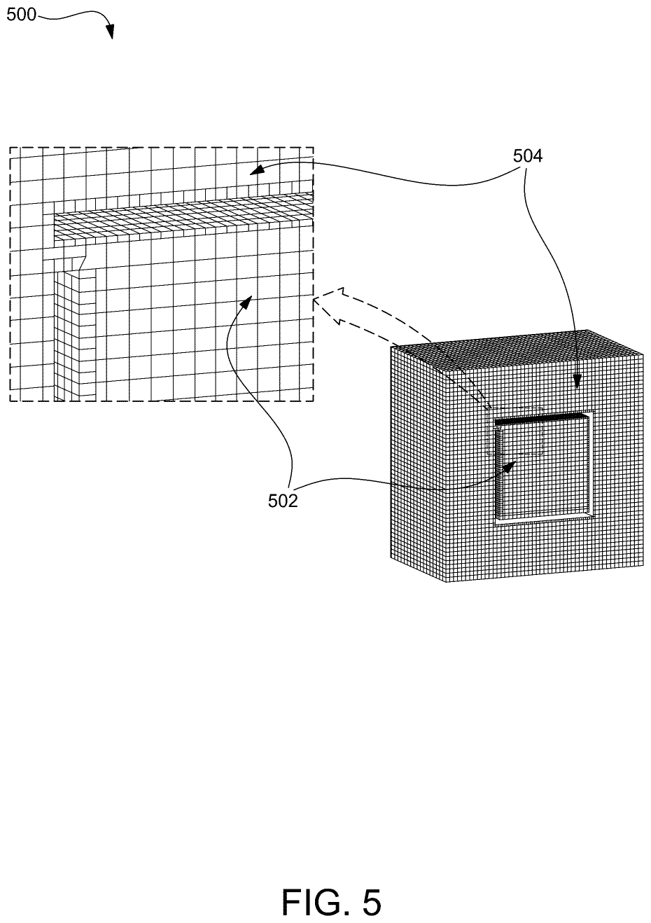

FIG. 5 is a diagram 500 that illustrates the separated volumes, in accordance with an embodiment of the present invention. This figure illustrates the final step of the “SEALS (super-efficient automatic leakage stopper)” algorithm, where the user separates an inner volume 502 and an outer volume 504 after identifying and scaling the gaps. In the image on the right bottom, the outer region represents the outer volume 504, while the inner region indicates the inner volume 502 of the hollow box 102. Once the user is satisfied with the location of the cut-off (where the gap has been sealed), they can execute a command to separate these volumes at the desired location. This separation is critical because it enables the model to accurately reflect the intended geometry, with a distinct boundary between the interior and exterior. The left side of the figure provides a closer view of the separation process, showing the precise interface between the inner and outer volumes 502 and 504. This division allows the user to select which volume to retain for the simulation, depending on the nature of the analysis they wish to conduct. For instance, in fluid dynamics or thermal simulations, isolating the inner volume may be necessary to understand internal flows or heat transfer. The algorithm's flexibility to separate and retain volumes ensures the model is correctly prepared for accurate and effective simulations, significantly enhancing the reliability of simulation outcomes. This capability streamlines the preparation process, eliminating manual efforts to seal gaps and verify geometries, ultimately improving the efficiency of the design validation workflow.

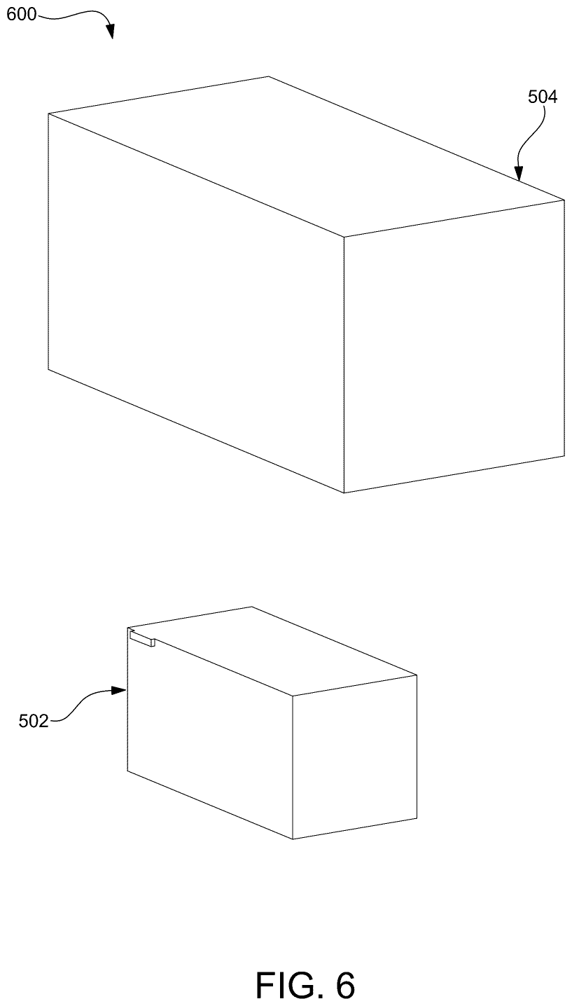

FIG. 6 is a diagram 600 that illustrates before and after deleting the outer volume, in accordance with an embodiment of the present invention. The figure demonstrates the final outcome of the “SEALS (super-efficient automatic leakage stopper)” algorithm after the separation of the inner and outer volumes 502 and 504. The top image shows the model with both volumes present, representing the state before deleting the outer volume 504. The inner volume 502 is still encased within the outer one 504, as a result of the previously defined boundary separation. The bottom image shows the model after the outer volume 504 has been removed, leaving behind the clean inner volume 502. This process is crucial for simulations that focus exclusively on the internal characteristics of the model, such as airflow, thermal distribution, or fluid dynamics, as it isolates the area of interest and eliminates unnecessary geometric complexities. By allowing the user to easily delete the outer volume 504, the algorithm provides a streamlined way to prepare the model for various simulation tasks. The clean inner volume 502 now correctly reflects the geometry intended for analysis, without the interference of external elements or gaps. This automated process ensures a more accurate simulation environment and reduces the manual labor traditionally required to fix such models, improving both the efficiency and reliability of the design validation workflow.

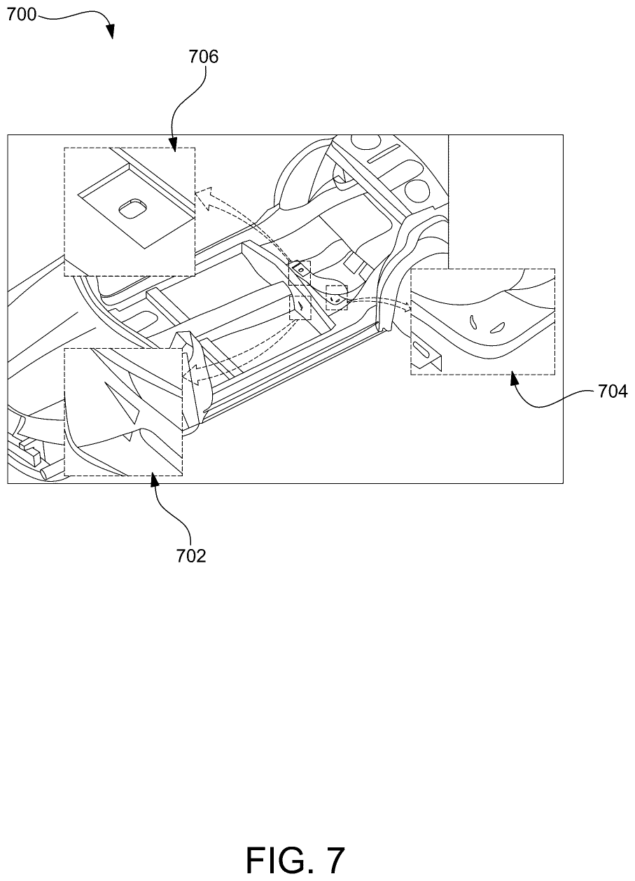

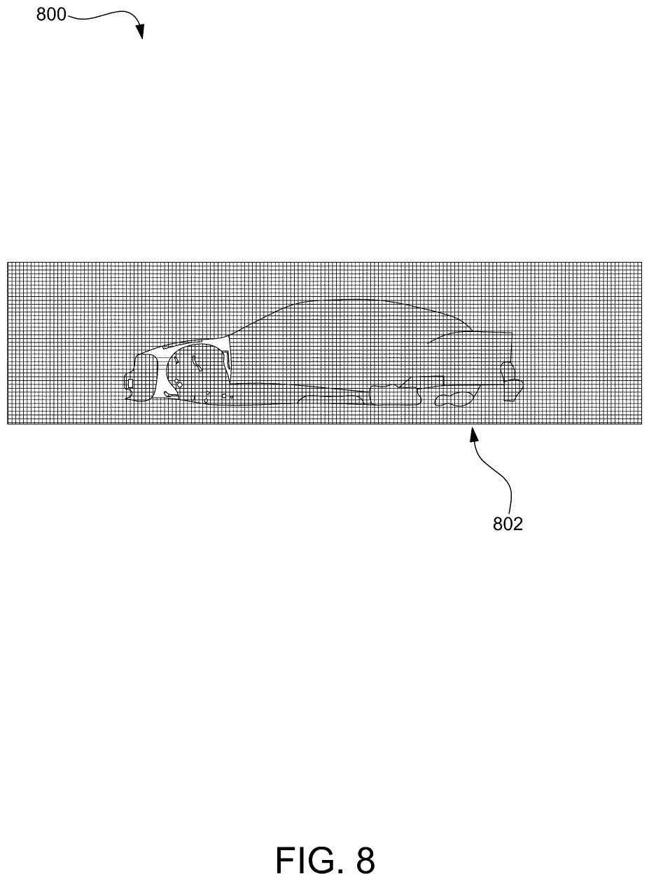

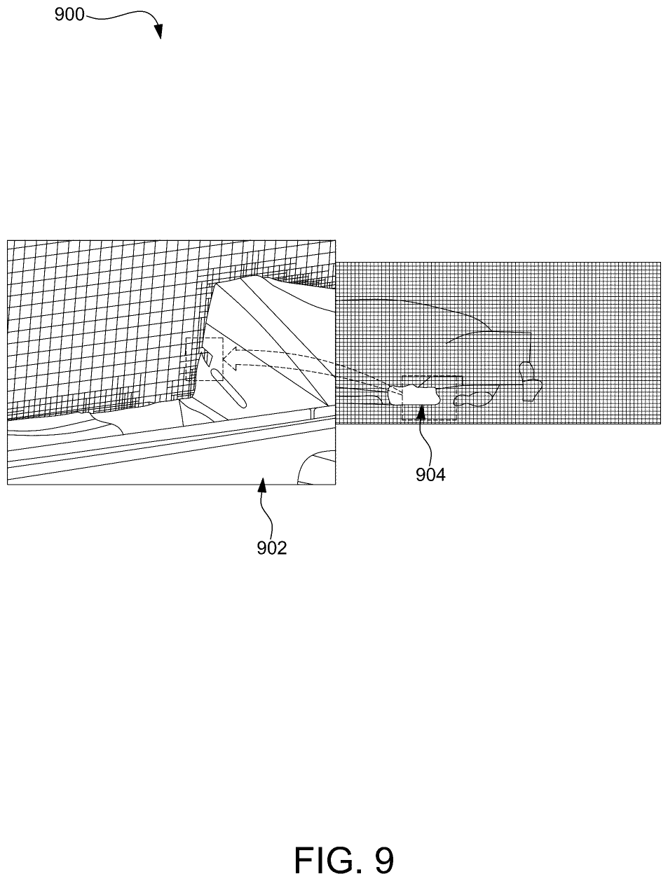

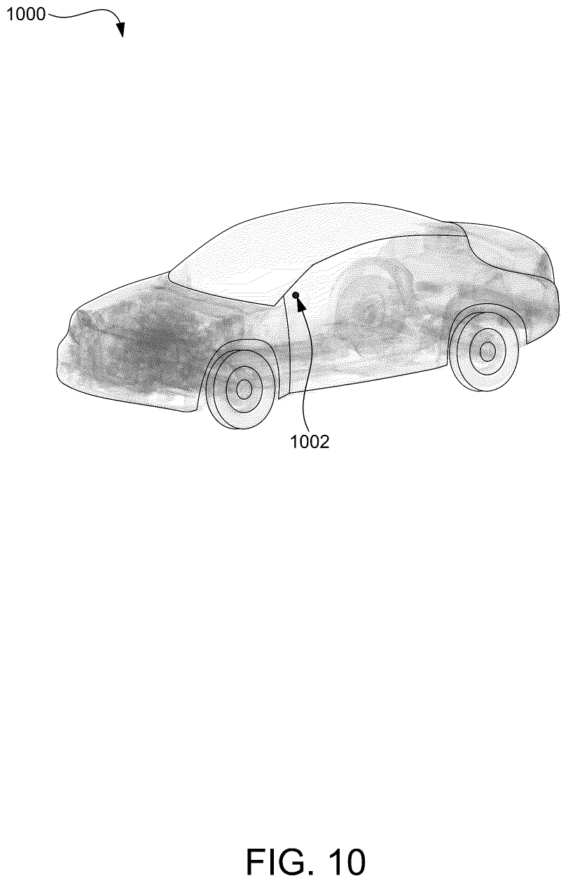

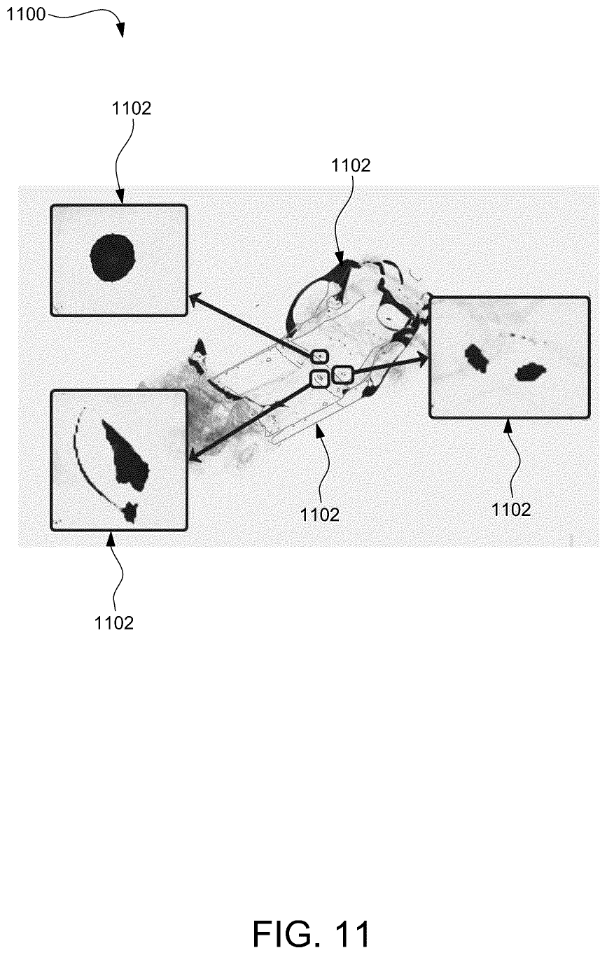

FIGS. 7-11 are diagrams 700-1100 that illustrate an exemplary solution, in accordance with an embodiment of the present invention. FIG. 7 highlights common issues in CAD models where small gaps, slivers, and mismatches between surfaces cause unintended leaks in the geometry. The zoomed-in sections 702, 704, and 706 emphasize various types of geometric defects, such as missing surfaces, small openings, and misaligned edges. These defects prevent the accurate generation of a simulation-ready model, leading to incorrect results in computational fluid dynamics (CFD) or finite element analysis (FEA). FIG. 8 demonstrates how meshing algorithms fail when gaps exist in the CAD model. The generated mesh 802 leaks from the internal volume of the vehicle to the external space, disrupting the distinction between the inside and outside regions. This leads to incorrect physics calculations in simulations, as fluid flow, heat transfer, or structural loads cannot be properly constrained to their designated areas. FIG. 9 shows a zoomed-in view 902 of a specific leak 904 in the CAD model, where the mesh extends through an unintended opening. This demonstrates the importance of detecting and sealing such leaks before running simulations. The system applies a mathematical solver, such as the Laplace equation, to identify these discontinuities in the primary variable distribution, allowing for automated detection of leak paths. FIG. 10 presents a transparency-based visualization 1000 of the CAD model, enabling a clear inspection of the internal and external structures. The model is processed using the proposed algorithm to analyze connectivity between volumes and ensure that leaks are properly identified. A marker 1002 indicates a key evaluation point within the model. FIG. 11 illustrates the automated solution for sealing CAD model gaps. The highlighted areas 1102 represent detected gaps and the regions affected by the sealing process. The algorithm dynamically adjusts the iso-surface threshold to close these gaps, ensuring the correct separation of inside and outside volumes. This step ensures that the cleaned CAD model is ready for simulation without leakage issues. These exemplary figures (FIGS. 7-11) collectively demonstrate how the invention detects, analyzes, and automatically seals CAD model gaps using a multi-step meshing, Laplace equation solving, and iso-surface adjustment process. The method improves simulation accuracy, reduces manual CAD correction efforts, and enhances the reliability of engineering analysis workflows.

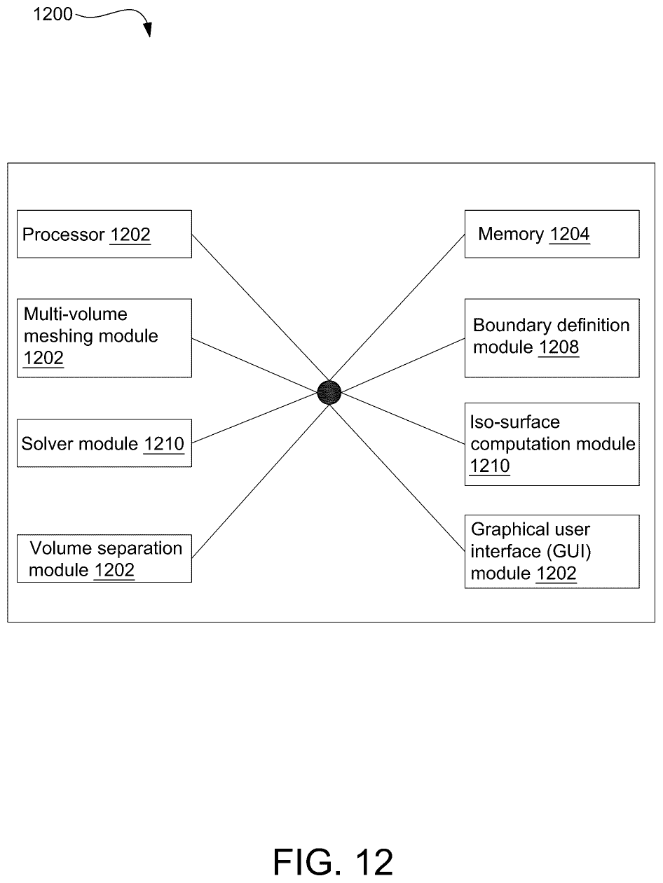

FIG. 12 is a block diagram 1200 that illustrates a system for performing the disclosed method operation, in accordance with an embodiment of the present invention. The system includes one or more components or modules such as a processor 1202, a memory 1204, a multi-volume meshing module 1206, a boundary definition module 1208, a solver module 1210, an iso-surface computation module 1212, a volume separation module 1214, and a graphical user interface (GUI) module 1216, but should not be construed as limiting to the scope of the present invention.

The processor 1202 is the central computational unit responsible for executing the algorithms required for detecting and sealing gaps in CAD models. The processor 1202 may be configured to handle mathematical operations, iterative computations, and logical decision-making within the system. For example, the processor 1202 may be configured to execute numerical solvers such as the Laplace equation solver to compute the primary variable distribution and identify geometric discontinuities. The processor 1202 may be further configured to manage the data flow between different modules, ensuring efficient processing of large 3D models. For example, during gap detection, the processor executes a finite element method (FEM) or finite difference method (FDM) to evaluate the mesh connectivity and detect where corrections are required.

The memory 1204 stores both temporary and permanent data necessary for processing CAD models. This includes volatile memory (RAM), which is used to hold temporary computational results, and non-volatile memory (SSD/HDD) for storing mesh data, boundary definitions, and simulation-ready models. The memory 1204 is crucial for storing multi-volume mesh representations, precomputed iso-surface solutions, and iterative refinement data. For example, once the Laplace equation is solved, the memory 1204 holds the resulting scalar field data, allowing the system to extract iso-surfaces and make necessary adjustments without recomputing the entire model from scratch.

The multi-volume meshing module 1206 may be configured to generate a computational mesh that accurately represents the CAD geometry, including all relevant bodies and surfaces for simulation. It partitions the model into finite elements or computational cells, allowing numerical solvers to operate efficiently. This module 1206 supports adaptive meshing, refining the mesh near detected gaps to improve resolution and accuracy. For example, in CFD simulations, this module ensures that air-tight separations exist between interior and exterior regions, preventing simulation errors due to mesh leakage. If gaps are detected, the module 1206 refines the mesh by introducing additional elements along discontinuous surfaces to aid in correction.

The boundary definition module 1208 may be configured to allow users or the system to specify inside and outside regions of the CAD model. This module 1208 is essential for ensuring that gaps are properly identified and classified for sealing. It operates by assigning boundary conditions to regions of the model and differentiating between internal and external volumes. For example, in a thermal analysis, the boundary definition module 1208 ensures that heat flow constraints are properly applied to the inner structure while preventing leakage into unintended external regions. It also provides interactive tools for users to manually refine boundary definitions if required.

The solver module 1210 may be configured for executing mathematical equations, such as the Laplace equation, over the multi-volume mesh to detect and seal gaps. This module 1210 employs numerical techniques such as finite element analysis (FEA), finite difference methods (FDM), or finite volume methods (FVM) to compute solutions. The solver module 1210 identifies rapid changes in the primary variable near discontinuities, which indicate the presence of gaps. For example, in an airflow simulation of a car cabin, this module 1210 detects unintended openings where airflow should not occur and generates corrective values to seal them. The solver module 1210 also supports parallel computation, enabling efficient processing of large-scale CAD models.

The iso-surface computation module 1212 may be configured to extract surfaces from the scalar field generated by the solver module 1210. An iso-surface is a continuous surface within the computational domain where the primary variable (such as temperature, pressure, or potential) maintains a constant value. This module 1212 iteratively adjusts the iso-surface threshold value to seal detected gaps. For example, in gap-scaling applications, the iso-surface computation module 1212 modifies threshold values until all detected leaks are closed, ensuring complete separation of internal and external volumes. It enables precision control, allowing gaps to be sealed one at a time if necessary.

The volume separation module 1214 divides the CAD model into distinct inner and outer volumes once the gaps are sealed. This ensures that the final model is correctly structured for simulation, eliminating any erroneous connections between internal and external regions. The module 1214 utilizes mesh segmentation techniques, leveraging the computed iso-surface to separate the geometry into closed, independent regions. For example, in automotive aerodynamics simulations, this module 1214 ensures that the airflow domain is properly isolated from the vehicle's internal components, preventing unintended airflow leakage. It also supports selective volume deletion, allowing users to remove unneeded portions of the model before running simulations.

The GUI module 1216 provides an interactive platform for the users to visualize, inspect, and modify CAD models during the gap-sealing process. It enables real-time rendering of 3D geometry, overlaying boundary conditions, iso-surfaces, and detected gaps for user inspection. The GUI 1216 allows the users to manually adjust iso-surface thresholds, redefine boundaries, and validate sealed regions before proceeding with simulations. For example, in aerospace structural simulations, engineers can use the GUI 1216 to verify that pressurized compartments are fully enclosed and adjust parameters as needed. The GUI 1216 also provides cross-sectional views, enabling users to inspect internal modifications in detail.

The operation begins with the creation of a multi-volume mesh that encompasses all bodies and surfaces of the 3D model relevant to a simulation. This mesh serves as the foundation for numerical computations and ensures that the entire geometry is accounted for during processing. The method then proceeds to define boundaries or points within the model to differentiate the inside and outside regions, where gaps are identified as the discontinuities between these regions. The invention then applies a mathematical approach to solving these gaps using an equation that satisfies specific conditions: the primary variable has a maximum value either at the boundaries or a source point, its gradient is inversely proportional to the area it traverses, and in the absence of gaps, it results in two constant values for the inside and outside regions. The Laplace equation is chosen due to its computational simplicity and suitability for ensuring smooth separation between volumes. Once the equation is set up, active and inactive volumes are defined, and all other boundaries are assigned a zero-gradient condition to ensure that the solution does not interfere with already stable regions. The next step involves finding an iso-surface of the primary variable solution, which represents a surface where the solution maintains a constant value. The iso-surface value is iteratively adjusted until the gaps in the 3D model are successfully sealed. This iterative approach ensures that gaps are precisely closed by continuously modifying the iso-surface values until the primary variable exhibits rapid changes near the detected gaps, signaling that the gap-scaling operation has been completed. The numerical solver dynamically adjusts the iso-value based on the rate of change of the primary variable across the mesh, further refining the process. The mesh refinement process is adaptive, meaning the meshing resolution is automatically refined near detected gaps to improve the accuracy of sealing, thus ensuring a robust model for subsequent simulations.

The separation of inside and outside volumes is performed by leveraging the computed iso-surface, effectively scaling the gaps and partitioning the geometry into distinct volumes. To enhance accuracy, this volume separation step is performed iteratively until a predefined convergence criterion is met, ensuring boundary integrity and preventing any unintentional connections between regions. The user is provided with the GUI that allows interactive boundary specification, enabling manual refinement of the inside and outside regions before gap-scaling occurs. Additionally, the GUI allows for real-time visualization of the iso-surface threshold values so that users can inspect the scaling process and make any necessary adjustments. To facilitate detailed analysis, the method also includes a cross-sectional view feature that enables users to visually inspect the model along the iso-surface, providing deeper insight into how the gaps are being sealed. Once the volumes have been successfully separated, the system allows for the selective deletion of the inner or outer volume, giving the users the ability to retain only the clean model necessary for simulation. This is particularly useful in scenarios where only one volume, such as an internal airflow domain, is required for analysis while the external shell is removed. Before finalizing the model, the system performs a volume integrity check to validate that all sealed regions are enclosed without residual gaps, ensuring a fully enclosed structure that meets the requirements of FEA and CFD simulations. Furthermore, the system automatically generates a simulation-ready CAD file format, ensuring compatibility with industry-standard simulation tools. This automation removes the need for manual CAD repair, expediting the transition from design to analysis. The algorithm incorporates a priority-based classification system that automatically categorizes gaps based on their size and shape, applying a hierarchical approach to first close gaps that most significantly impact simulation stability. For example, large leaks in an airflow simulation would be prioritized over minor surface imperfections, optimizing the gap-sealing sequence for efficiency. Additionally, the system detects and logs all sealed gaps, providing an audit trail that allows users to review modifications and verify the structural integrity of the CAD model. This feature is essential for regulatory compliance and quality control in industries such as automotive and aerospace design. To ensure robustness, an error-correction module is included, which identifies any regions where the Laplace equation solution fails to achieve stable volume separation. If such errors are detected, the module reprocesses the affected areas, adjusting meshing parameters, modifying boundary conditions, or refining numerical tolerances to ensure complete and stable sealing of the CAD model. This redundancy ensures that even in complex geometries, no gaps remain unsealed, preserving simulation accuracy and preventing errors that could compromise engineering analysis. The disclosed invention operates as a comprehensive, automated system for identifying, classifying, sealing, and validating gaps in 3D CAD models. By combining numerical solvers, adaptive meshing, real-time visualization, user interactivity, and automated model preparation, the disclosed invention drastically improves the efficiency and reliability of simulation-ready CAD models.

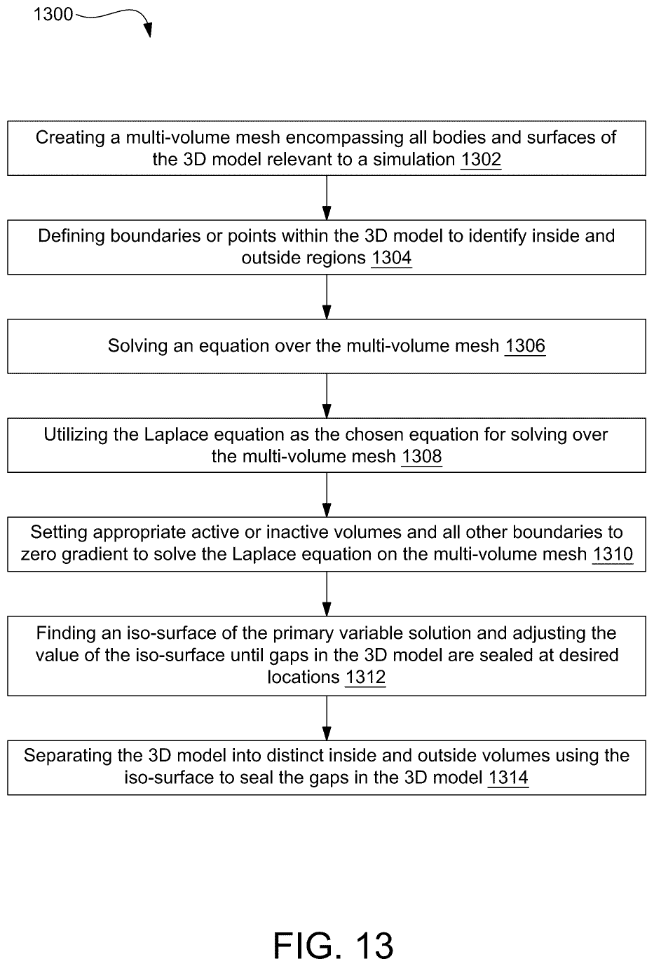

FIG. 13 is a diagram 1300 that illustrates a flowchart of a method for automatically identifying and scaling gaps in a geometrical or three-dimensional model for simulation purposes, in accordance with an embodiment of the present invention. At step 1302, the method includes creating a multi-volume mesh encompassing all bodies and surfaces of the 3D model relevant to a simulation. At step 1304, the method includes defining boundaries or points within the 3D model to identify inside and outside regions, wherein gaps are located between the inside and outside regions. At step 1306, the method includes solving an equation over the multi-volume mesh, wherein the equation satisfies the conditions that its primary variable has a maximum value either at the boundaries or at a source point, has a gradient inversely proportional to the area through which it can pass, and results in two constant values for the inside and outside regions in the absence of gaps. At step 1308, the method includes utilizing the Laplace equation as the chosen equation for solving over the multi-volume mesh. At step 1310, the method includes setting appropriate active or inactive volumes and all other boundaries to zero gradient to solve the Laplace equation on the multi-volume mesh. At step 1312, the method includes finding an iso-surface of the primary variable solution and adjusting the value of the iso-surface until gaps in the 3D model are sealed at desired locations. At step 1312, the method includes separating the 3D model into distinct inside and outside volumes using the iso-surface to seal the gaps in the 3D model.

The computer-implemented method 1300 for automatically identifying and scaling gaps in a three-dimensional (3D) model for simulation purposes begins with the creation of a multi-volume mesh that encompasses all bodies and surfaces of the 3D model. This multi-volume meshing process ensures that all geometric components relevant to simulation are represented, enabling precise identification of internal and external regions. The method then proceeds to define boundaries or points within the model to differentiate inside and outside volumes, where gaps are recognized as discontinuities that must be corrected before the model is used for simulation. These gaps can occur due to tolerances, surface misalignments, or assembly issues, and they pose a significant challenge in maintaining the accuracy of CFD and FEA simulations. The definition of boundaries can be performed automatically by the system or manually by the user through a graphical user interface (GUI), ensuring that critical regions are correctly identified. Once the inside and outside regions are defined, the system proceeds to solve an equation over the multi-volume mesh that is designed to analyze and separate the connected regions. The chosen equation satisfies three key conditions: (1) the primary variable has a maximum value at the boundaries or at the source point, (2) its gradient is inversely proportional to the area it traverses, and (3) in the absence of gaps, the solution results in two constant values distinguishing the inside and outside volumes. The Laplace equation is selected for solving over the multi-volume mesh due to its simplicity and suitability in detecting geometric discontinuities. The Laplace equation is solved using a finite element method (FEM) or finite difference method (FDM) to ensure high precision in the detection and separation of inside and outside volumes. During this process, active and inactive volumes are assigned, and all other boundaries are set to a zero-gradient condition, ensuring that the equation's solution only influences regions containing gaps without altering the rest of the model. Following the solution of the Laplace equation, the method proceeds with finding an iso-surface of the primary variable solution. The iso-surface represents a constant value of the primary variable and serves as a separator between regions within the model. To effectively seal gaps, the iso-surface value is iteratively adjusted until the gaps are entirely closed at the desired locations. The adjustment process is performed dynamically using a numerical solver, which modifies the iso-value based on the rate of change of the primary variable across the mesh. The system continuously monitors for rapid changes in the primary variable around the gap locations, ensuring that each identified gap is completely sealed before finalizing the process. To enhance accuracy, the multi-volume mesh generation process incorporates an adaptive meshing technique that refines the mesh resolution near detected gaps. This ensures that even small slivers, surface mismatches, or micro-gaps are identified and addressed, preventing errors in high-fidelity simulations.

Once the gaps are sealed, the 3D model is separated into distinct inside and outside volumes using the computed iso-surface. This volume separation step is performed iteratively to refine the mesh until a predefined convergence criterion for boundary integrity is met, ensuring that the separation is both stable and accurate. The method further provides an interactive graphical user interface (GUI) that allows users to modify the iso-surface threshold values, define boundaries, and visually inspect the sealing process in real time. The GUI also enables users to view a cross-sectional representation of the model along the iso-surface, providing a detailed visual verification of the sealing process. Additionally, the system automatically classifies gaps based on their size and shape, prioritizing the sealing of gaps that significantly impact simulation stability before addressing smaller ones. This priority-based approach ensures computational efficiency while maintaining the highest level of accuracy. Following volume separation, the method allows users to selectively delete one of the volumes, either the inner volume or the outer volume, to retain a clean, simulation-ready model. This feature is particularly useful in applications such as CFD simulations, where only the internal airflow domain needs to be retained, while the solid exterior is discarded. Before finalizing the model, the system performs a volume integrity check to validate that all sealed regions are fully enclosed without residual gaps, ensuring that the model is completely airtight and suitable for simulation. If any inconsistencies are found, an error-correction module is activated, which reprocesses the affected areas and ensures that all gaps are sealed before proceeding. The system detects and logs all scaled gaps, maintaining a detailed audit trail that allows users to review modifications and verify the structural integrity of the CAD model. Further, the method automatically generates a simulation-ready CAD file format that is compatible with industry-standard simulation tools, including Finite Element Analysis (FEA), Computational Fluid Dynamics (CFD), and other engineering applications. This ensures that the cleaned, gap-free model can be seamlessly integrated into simulation workflows without requiring further manual adjustments. By automating the entire process of gap identification, sealing, validation, and CAD file generation, the invention eliminates manual intervention, reduces the time required for CAD preparation, and significantly improves the accuracy and efficiency of engineering simulations.

In many practical scenarios, particularly in industries involving legacy components, aftermarket parts, or scanned prototypes, 3D models are not generated from parametric CAD design but rather reverse-engineered from physical objects. This process often begins with 3D scanning technologies, which produce a point cloud: a dense set of spatial data points representing the surface geometry of the scanned object. These point cloud files, though visually representative, are inherently noisy, non-parametric, and prone to irregularities, including small discontinuities, overlapping regions, and undefined surface boundaries. As such, when these point clouds are later converted into STL files or other mesh-based formats using reconstruction software, they often suffer from the same or even more severe gaps, slivers, and surface inconsistencies as native CAD models. The present invention is particularly applicable to such reverse-engineered geometries. When applied to point cloud-derived meshes, the disclosed method offers substantial advantages in detecting and sealing structural discontinuities that commonly arise from scanner noise, meshing artifacts, or imperfect surface generation algorithms. The Laplace-based solver, combined with iso-surface evaluation or alternative boundary differentiation techniques (e.g., high gradient detection), allows for robust handling of irregular geometries and supports automated conversion of noisy, scanned data into simulation-ready models. This capability addresses a critical gap in the current simulation pipeline, where manual repair of scan-derived files is often laborious and error-prone. The disclosed method can be adapted to begin directly with mesh surfaces derived from point clouds, bypassing the need for mathematically well-defined solids. By treating surface meshes as boundary inputs, the algorithm can construct a pseudo-volume mesh, define inner and outer boundary regions, and apply the same Laplace-based sealing techniques to effectively distinguish and isolate volumes. This extension of the method supports broader applications, such as heritage part analysis, biomechanical modeling from anatomical scans, and reverse-engineered aerospace or automotive components, where simulation from scanned data is increasingly common.

The present invention offers significant advantages by automating the identification and scaling of gaps in 3D CAD models, eliminating the need for manual correction, which is often time-consuming and error-prone. By leveraging multi-volume meshing, numerical solvers, and adaptive iso-surface computation, the method ensures high precision in detecting and closing even microscopic gaps, preventing mesh leakage and simulation errors in CFD and FEA applications. The iterative refinement process enhances accuracy while optimizing computational resources, ensuring that only necessary regions are reprocessed. Additionally, the GUI provides real-time interaction, allowing users to visually inspect, modify iso-surface thresholds, and validate the sealing process with cross-sectional views. The system's ability to automatically classify gaps, prioritize critical areas, and generate simulation-ready CAD files enhances workflow efficiency, making it highly applicable to automotive, aerospace, industrial design, and other engineering simulations. The incorporation of an error-correction module, volume integrity validation, and audit logging further improves reliability, accuracy, and compliance with industry standards, ensuring a seamless transition from CAD modeling to simulation.

The present invention should not be considered as abstract because it provides a concrete and technical solution to a well-defined problem in the field of CAD modeling and simulation preparation. The invention is implemented through a specific series of computational steps involving multi-volume meshing, numerical solvers, iso-surface computation, and adaptive volume separation. These steps ensure that gaps in 3D models are automatically identified, classified, and sealed, allowing for accurate simulation without manual intervention. The method requires specialized mathematical computations, such as solving the Laplace equation using finite element or finite difference methods, which are not generic or abstract but rather highly technical implementations tailored to the problem of mesh leakage in CAD-based simulations. Unlike abstract ideas that merely describe an end result without detailing how it is achieved, this invention specifies the particular algorithms, data structures, and computational processes required to perform the gap-scaling operation. Furthermore, the invention is tied to a specific technological field, namely, CAD modeling, computational simulation, and finite element analysis, where it directly improves the efficiency and accuracy of engineering workflows. The automated method involves real-time interaction through the GUI, iterative refinements of iso-surface values, and volume separation with convergence criteria, ensuring that the computational results are not generic or theoretical but have practical applications in engineering design, automotive simulations, aerospace modeling, and manufacturing. The invention is designed to be used in conjunction with industry-standard simulation tools such as CFD and FEA solvers, demonstrating that it is inherently linked to real-world, physical applications rather than abstract theoretical concepts. The invention should also be considered as non-obvious because it introduces a novel and non-trivial approach to solving a persistent problem in CAD-based simulations. Conventional methods for preparing CAD models for simulation involve manual corrections, where engineers inspect and fix gaps one at a time, which is time-consuming, error-prone, and inefficient. Existing solutions do not provide a fully automated process that dynamically analyzes, classifies, and seals gaps using a combination of multi-volume meshing, Laplace equation solvers, adaptive meshing, and real-time iso-surface computation. The application of these multiple mathematical and computational techniques in a single framework for scaling CAD gaps is not an obvious extension of prior art but rather a unique and innovative integration of computational geometry, numerical solvers, and AI-driven decision-making for CAD processing. Moreover, prior techniques often rely on surface-based corrections, which only modify the outer layer of the geometry and fail to properly resolve internal gaps or volume discontinuities. The present invention expands beyond surface-level adjustments by performing internal volume separation and iterative refinement, ensuring that the entire CAD model is properly enclosed for simulation accuracy. Additionally, the incorporation of gap classification based on size and impact, automated model validation, and real-time user interaction through a GUI represents a significant departure from conventional manual and semi-automated methods. Another key aspect of non-obviousness is the use of adaptive meshing techniques that dynamically refine only the regions near detected gaps, thereby optimizing computational efficiency without unnecessarily increasing the complexity of the entire model. This aspect, combined with the invention's ability to generate a simulation-ready CAD file that integrates seamlessly with industry-standard solvers, highlights that the invention is not merely an incremental improvement but a fundamentally different and highly optimized approach to preparing CAD models for simulation.

The foregoing descriptions of specific embodiments of the present technology have been presented for purposes of illustration and description. They are not intended to be exhaustive or to limit the present technology to the precise forms disclosed, and obviously many modifications and variations are possible considering the above teaching. The embodiments were chosen and described to best explain the principles of the present technology and its practical application, to thereby enable others skilled in the art to best utilize the present technology and various embodiments with various modifications as are suited to the particular use contemplated. It is understood that various omissions and substitutions of equivalents are contemplated as circumstance may suggest or render expedient, but such are intended to cover the application or implementation without departing from the spirit or scope of the claims of the present technology.

While several possible embodiments of the invention have been described above and illustrated in some cases, it should be interpreted and understood as to have been presented only by way of illustration and example, but not by limitation. Thus, the breadth and scope of a preferred embodiment should not be limited by any of the above-described exemplary embodiments.

What is claimed is:

1. A computer-implemented method for automatically identifying and sealing gaps in a geometrical or three-dimensional model for simulation purposes, the method comprising:
creating a multi-volume mesh encompassing all bodies and surfaces of the 3D model relevant to a simulation;
defining boundaries or points within the 3D model to identify inside and outside regions, wherein gaps are located between the inside and outside regions;
solving an equation over the multi-volume mesh, wherein the equation satisfies the conditions that its primary variable has a maximum value either at the boundaries or at a source point, has a gradient inversely proportional to the area through which it can pass, and results in two constant values for the inside and outside regions in the absence of gaps;
utilizing the Laplace equation as the chosen equation for solving over the multi-volume mesh;
setting appropriate active or inactive volumes and all other boundaries to zero gradient to solve the Laplace equation on the multi-volume mesh;
finding an iso-surface of the primary variable solution and adjusting the value of the iso-surface until gaps in the 3D model are sealed at desired locations; and
separating the 3D model into distinct inside and outside volumes using the iso-surface to seal the gaps in the 3D model.

2. The method of claim 1, wherein the adjustment of the iso-surface value is performed iteratively until the primary variable changes rapidly near the gaps, indicating successful sealing of the gaps.

3. The method of claim 1, wherein the step of defining boundaries or points includes allowing a user to interactively specify the boundaries or points within the model using a graphical user interface.

4. The method of claim 1, further comprising the step of displaying a cross-sectional view of the 3D model along the iso-surface to visually inspect the sealing of the gaps.

5. The method of claim 1, wherein the separated volumes include an inner volume and an outer volume, and further comprising the step of selectively deleting one of the volumes to retain a clean model for subsequent simulation.

6. The method of claim 1, wherein the multi-volume mesh is generated using an adaptive meshing technique that refines the mesh resolution near detected gaps to improve the accuracy of gap identification and sealing.

7. The method of claim 1, wherein the iso-surface of the primary variable solution is computed using a numerical solver that dynamically adjusts the iso-value based on the rate of change of the primary variable across the mesh.

8. The method of claim 1, wherein the Laplace equation is solved using a finite element or finite difference method to ensure precise detection and separation of inside and outside volumes.

9. The method of claim 1, further comprising a step of validating the sealed model by performing a volume integrity check to confirm that the inner and outer volumes are fully enclosed without residual gaps.

10. The method of claim 1, wherein a graphical user interface is provided to allow a user to interactively modify the iso-surface threshold values and visually inspect the sealing process in real time.

11. The method of claim 1, wherein the algorithm automatically classifies gaps based on their size and shape, applying a priority-based sealing approach to first close gaps that significantly impact simulation stability.

12. The method of claim 1, further comprising a step of automatically generating a simulation-ready CAD file format after sealing the gaps and separating the volumes, ensuring compatibility with finite element analysis (FEA), computational fluid dynamics (CFD), or other simulation tools.

13. The method of claim 1, wherein the separation of inside and outside volumes is performed iteratively to refine the mesh until a predefined convergence criterion for boundary integrity is met.

14. The method of claim 1, wherein the system detects and logs all sealed gaps, providing an audit trail for users to review modifications and verify the structural integrity of the modified CAD model.

15. The method of claim 1, further comprising an error-correction module that identifies and reprocesses any regions where the Laplace equation solution fails to achieve a stable separation of volumes, ensuring complete sealing of the CAD model.

16. A system for automatically identifying and sealing gaps in a three-dimensional (3D) computer-aided design (CAD) model for simulation, the system comprising:
a processor configured to execute instructions stored in a memory to perform gap identification and sealing;
a multi-volume meshing module configured to generate a mesh encompassing all CAD bodies and surfaces of the 3D model relevant to a simulation;
a boundary definition module configured to define boundaries or points within the 3D model to distinguish inside and outside regions, wherein gaps exist between these regions;
a solver module configured to execute a Laplace equation over the multi-volume mesh, wherein the equation satisfies the conditions that its primary variable has a maximum value either at the boundaries or in the source term, has a gradient inversely proportional to the area through which it can pass, and results in two constant values for the inside and outside regions in the absence of gaps;
an iso-surface computation module configured to determine an iso-surface of the primary variable solution and iteratively adjust its value until gaps in the 3D model are sealed at desired locations;
a volume separation module configured to segment the 3D model into distinct inside and outside volumes using the computed iso-surface, ensuring the gaps are sealed; and
a graphical user interface (GUI) module configured to allow a user to interactively define boundaries, visualize the iso-surface, inspect the sealing process, and selectively delete inner or outer volumes as needed for simulation preparation.
